(19) United States
(12) Patent Application Publication
(10) Pub. No.: US 2024/0268074 A1
(43) Pub. Date: Aug. 8, 2024

(54) HEAT DISSIPATION STRUCTURE FOR HEATING ELEMENT

(71) Applicant: GigaTera USA, Inc., Fullerton, CA (US)

(72) Inventor: Byung In KIM, Anaheim, CA (US)

(73) Assignee: GigaTera USA, Inc., Fullerton, CA (US)

(21) Appl. No.: 18/163,497

(22) Filed: Feb. 2, 2023

(51) Int. Cl. H05K 7/20

(52) U.S. Cl. CPC H05K 7/2039

(57) ABSTRACT

According to an embodiment of the present disclosure, a heat dissipation structure for a heating element is provided, wherein the heat dissipation structure uses a heat sink and includes: a plate; the heating element comprising a housing configured to have one surface attached to the plate and a heating unit positioned inside the housing and emitting heat; a vapor chamber positioned in close contact with the heating element and configured to receive and diffuse the heat emitted from the heating element; a thermal pad configured to transfer the heat received from the vapor chamber to the heat sink; and the heat sink attached to the thermal pad and configured to emit the heat received from the thermal pad.

### TECHNICAL FIELD

The present disclosure relates to a heat dissipation structure for a heating element.

### BACKGROUND

The content described in the present section simply provides background information for the present disclosure and does not constitute prior art.

Electronic devices such as mobile phones, LED modules, laptop computers, and personal computers (PCs) are widely used. Each electronic device may include a number of electric and electronic components such as a circuit board, a transceiver module, and a battery.

A heating element that generates heat is also included in the electric and electronic components. For example, heat is generated in elements such as high-power and high-output amplifying elements, high-speed and high-function Central Processing Units (CPUs), Digital Signal Processors (DSPs), and Field Programmable Gate Arrays (FPGAs).

Heat generated by a heating element may cause heat deterioration of the corresponding part or peripheral parts, thereby degrading the performance of the electronic device or causing malfunction or damage to the electronic device. Therefore, a heat dissipation structure is required inside the electronic device to effectively dissipate the heat generated by the heating element.

In order to dissipate the heat generated by the heating element, a heat dissipation structure using a heat sink, a heat pipe, a vapor chamber, or the like may be designed on the exterior of the heating element.

With the trend of high-integration and high-output of electronic devices, the heat dissipation performance of the heat dissipation structure using a heat sink or the like is becoming more important. However, there is a limit to improving the thermal conductivity of a material of the heat dissipation structure. Therefore, it is necessary to improve the heat dissipation performance of the heat dissipation structure by changing the design of the heat dissipation structure.

### SUMMARY

In a heat dissipation structure for a heating element according to an embodiment, a thermal compound may be positioned between the heating element and the vapor chamber, and one surface of the heating element may be open.

Objects to be achieved by the present disclosure are not limited to the object mentioned above, and other objects not mentioned will be clearly understood by those skilled in the art from the description below.

According to an embodiment of the present disclosure, a heat dissipation structure for a heating element that uses a heat sink includes: a plate; the heating element comprising a housing configured to have one surface attached to the plate and a heating unit positioned inside the housing and emitting heat; a vapor chamber positioned in close contact with the heating element and configured to receive and diffuse the heat emitted from the heating element; a thermal pad configured to transfer the heat received from the vapor chamber to the heat sink; and the heat sink attached to the thermal pad and configured to emit the heat received from the thermal pad.

According to one embodiment, the heat dissipation structure for a heating element has an effect of improving heat dissipation performance by placing a thermal compound between the heating element and the vapor chamber and opening one surface of the heating element.

### BRIEF DESCRIPTION OF THE DRAWINGS

FIG. 1 is a cross-sectional view of a conventional heat dissipation structure for a heating element.

FIG. 2 is a diagram illustrating a coupled state of a heat dissipation structure for a heating element according to an embodiment of the present disclosure.

FIG. 3 is an exploded view of a heat dissipation structure for a heating element according to an embodiment of the present disclosure.

FIG. 4 is a cross-sectional view of a heat dissipation structure for a heating element according to an embodiment of the present disclosure.

FIG. 5 is a table comparing thermal resistance of a conventional heat dissipation structure for a heating element and a heat dissipation structure for a heating element according to the present disclosure.

### DETAILED DESCRIPTION

Hereinafter, some exemplary embodiments of the present disclosure will be described in detail with reference to the accompanying drawings. In the following description, like reference numerals preferably designate like elements, although the elements are shown in different drawings. Furthermore, in the following description of various exemplary embodiments of the present disclosure, a detailed description of known functions and configurations incorporated therein will be omitted for clarity and for brevity

Additionally, various terms such as first, second, A, B, (a), (b), etc., are used solely to differentiate one component from the other but not to imply or suggest the substances, order, or sequence of the components. Throughout the present specification, when a part ‘includes’ or ‘comprises’ a component, the part is meant to further include other components, not to exclude thereof unless specifically stated to the contrary. The terms such as ‘unit’, ‘module’, and the like refer to one or more units for processing at least one function or operation, which may be implemented by hardware, software, or a combination thereof.

In order to avoid confusion in understanding the present disclosure, “upward” or “upper surface” refers to a direction in which a heat sink 15 is provided. Also, “downward” or “lower surface” refers to a direction in which a plate 11 is provided.

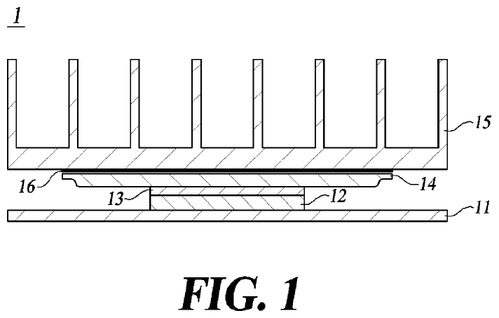

FIG. 1 is a cross-sectional view of a conventional heat dissipation structure for a heating element.

Referring to FIG. 1, a conventional heat dissipation structure 1 for a heating element may include at least one or all of a plate 11, a heating element 12, a thermal pad 13, a vapor chamber 14, a heat sink 15, or a thermal compound 16.

The heating element 12 may be attached to an upper surface of the plate 11. The thermal pad 13 and the vapor chamber 14 may be sequentially attached to an upper surface of the heating element 12. The thermal pad 13 is in the form of a double-sided tape containing an adhesive material, so that the heating element 12 and the vapor chamber 14 may be attached to opposing lower and upper surfaces of the thermal pad 13, respectively. The heat sink 15 may be attached to an upper surface of the vapor chamber 14.

The thermal compound 16, which is a fluid that transfers heat, may be applied between the vapor chamber 14 and the heat sink 15. That is, the thermal compound 16 may be applied to an interface between the upper surface of the vapor chamber 14 and the lower surface of the heat sink 15.

A heat dissipation mechanism of the conventional heat dissipation structure 1 for a heating element will be briefly described below. Heat generated by the heating element 12 may be transferred to the thermal pad 13. The thermal pad 13 may transfer the heat received from the heating element 12 to the vapor chamber 14. The vapor chamber 14 may diffuse the heat received from the thermal pad 13 to the heat sink 15.

The vapor chamber 14 may transfer heat, which is received by internal steam from the thermal pad 13 provided below the lower surface of the vapor chamber 14, to the heat sink 15 provided on the upper surface of the vapor chamber 14. In order to effectively diffuse heat, a cross-sectional area of the upper surface of the vapor chamber 14 may be larger than a cross-sectional area of the lower surface of the vapor chamber 14.

Heat diffused by the vapor chamber 14 may be transferred to the heat sink 15 through the thermal compound 16. The heat sink 15 may include a plurality of heat dissipation pins formed at predetermined intervals on an upper surface thereof. The heat sink 15 may dissipate heat using the plurality of heat dissipation pins. As a result, heat generated by the heating element 12 may be emitted.

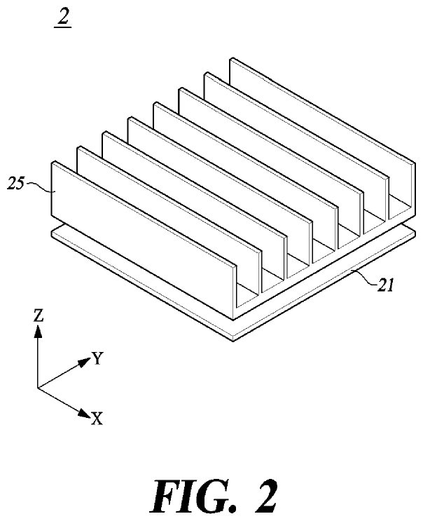

FIG. 2 is a diagram illustrating a coupled state of a heat dissipation structure for a heating element according to an embodiment of the present disclosure.

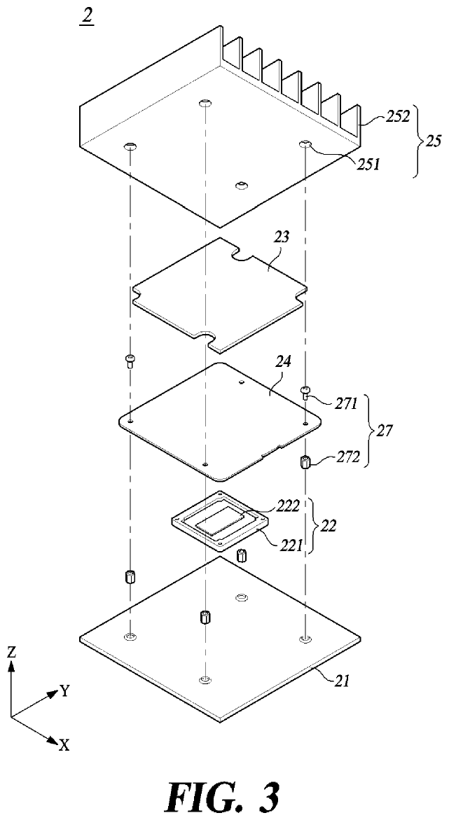

FIG. 3 is an exploded view of a heat dissipation structure of a heating element according to an embodiment of the present disclosure.

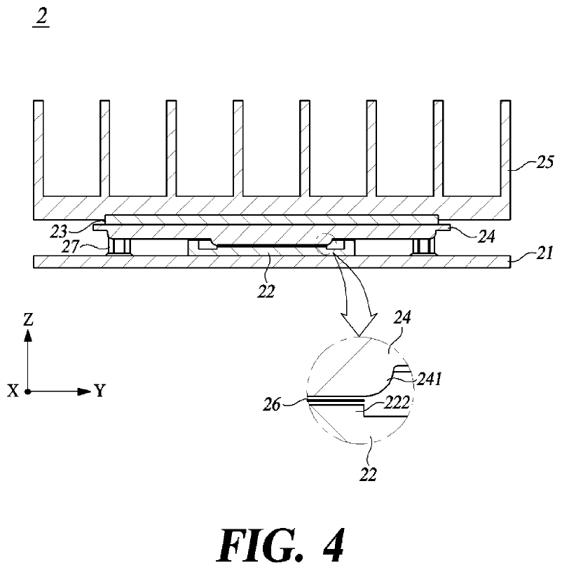

FIG. 4 is a cross-sectional view of a heat dissipation structure for a heating element according to an embodiment of the present disclosure.

Referring to FIGS. 2 to 4, a heat dissipation structure 2 for a heating element according to the present disclosure may include at least one or all of a plate 21, a heating element 22, a thermal pad 23, a vapor chamber 24, a heat sink 25, a thermal compound 26, or a connecting member 27.

The heat dissipation structure 2 for a heating element according to the present disclosure has different design positions of the thermal pad 23, the vapor chamber 24 and the thermal compound 26 compared to the conventional heat dissipation structure 1 for a heating element. In addition, one surface of the heating element 22 may be open. Due to the changed design position and one surface of the heating element 22 being open, heat dissipation performance of the heat dissipation structure 2 for a heating element may be improved. Compared to the conventional heat dissipation structure 1 for a heating element, description of common or corresponding parts have been omitted.

The heating element 22 may include a housing 221 and a heating unit 222. The housing 221 may have a lidless shape with an open upper surface. A lower surface of the housing 221 may be attached to the plate 21. The heating unit 222 may be positioned at the center inside of the housing 221. In this case, the heating unit 222 may be a device having a heat dissipation area smaller than a cross-sectional area of the housing 221, such as a Field Programmable Gate Array (FPGA). By using the lidless housing 221, thermal resistance of a lid is removed, so that the heat dissipation performance of the heat dissipation structure 2 for a heating element can be improved.

The vapor chamber 24 may be positioned to be in close contact with the heating element 22. Specifically, a protrusion unit 241 may be formed on a lower surface of the vapor chamber 24, and at least a portion of the protrusion unit 241 may be positioned to be inserted into the housing 221.

The thermal compound 26 may be applied between the vapor chamber 24 and the heating element 22. Specifically, the thermal compound 26 may be applied to an interface between a lower surface of the protruding portion 241 and an upper surface of the heating unit 222. The thermal compound 26 is a thermal interface material (TIM) having a minimum thickness and may minimize thermal resistance. Since the thermal compound 26 is applied to the upper surface of the heating unit 222 having a small cross-sectional area, an area of application of the thermal compound 26 of the present disclosure may be smaller than that of the conventional thermal compound 16.

In order to effectively diffuse heat, the upper surface of the vapor chamber 24 may have a larger cross-sectional area than that of the lower surface of the vapor chamber 24. Accordingly, it is possible to widely diffuse heat transferred from the heating unit 222 having a smaller cross-sectional area.

The thermal pad 23 may be attached to the upper surface of the vapor chamber 24. Since the thermal pad 23 is attached to the upper surface of the vapor chamber 24, which has a larger cross-sectional area than that of the lower surface of the vapor chamber 24, a cross-sectional area of the thermal pad 23 of the present disclosure may be larger than that of the conventional thermal pad 13.

The heat sink 25 may be attached to the upper surface of the thermal pad 23. The thermal pad 23 is in the form of a double-sided tape containing an adhesive material so that the vapor chamber 24 and the heat sink 25 may be attached to opposing lower and upper surfaces of the thermal pad 23, respectively. Although the thermal compound 26 has higher heat transfer efficiency than the thermal pad 23, the thermal pad 23 may be positioned between the vapor chamber 24 and the heat sink 25 so as to absorb cumulative tolerance in a height direction (z axis) of the heat dissipation structure 2 for a heating element.

The heat sink 25 may include a plurality of heat dissipation pins 252 formed at predetermined intervals on the upper surface thereof. The plurality of heat dissipation pins 252 may protrude from the upper surface of the heat sink 25 in the z-axis direction and may be formed at predetermined intervals in the y-axis direction.

The connecting member 27 may include a screw 271 and a spacer 272. The spacer 272 may be positioned between the vapor chamber 24 and the plate 21. The spacer 272 may prevent the heating element 22 from being over-pressurized by the vapor chamber 24, the thermal pad 23, and the heat sink 25. The spacer 272 may be replaced with a spacer 272 having an appropriate height if necessary.

A lower end of the spacer 272 may be coupled to the plate 21 by soldering. An upper end of the spacer 272 may have a screw hole through which the screw 271 can be inserted. The screw 271 may pass through the vapor chamber 24 from top to bottom and may be coupled to the spacer 272.

A plurality of grooves 251 may be formed on a lower surface of the heat sink 25. Screws 271 may be respectively accommodated in the plurality of grooves 251 of the heat sink 25. As the screws are respectively accommodated in the plurality of grooves, the heat sink 25, the thermal pad 23, and the vapor chamber 24 may be closely bonded.

Referring to FIG. 1 and FIG. 4, the thermal compound 26 according to the present disclosure may be applied to a smaller area, compared to the conventional thermal compound 16. On the other hand, the cross-sectional area of the thermal pad 23 according to the present disclosure may be larger than that of the conventional thermal pad 13. That is, as the design positions of the thermal pad 23, the vapor chamber 24, and the thermal compound 26 are changed, an area of application of the thermal compound 26 and a cross-sectional area of the thermal pad 23 may be different from those of the related art.

As the area of application of the thermal compound 26 and the cross-sectional area of the thermal pad 23 are changed, the thermal resistances of the thermal compound 26 and the thermal pad 23 are changed. Since the thermal resistances of the thermal compound 26 and the thermal pad 23 are changed, the heat dissipation performance of the heat dissipation structure 2 for a heating element may be improved. Change in heat dissipation performance of the heat dissipation structure 2 for a heating element due to the changes in the area of application of the thermal compound 26 and the cross sectional area of the thermal pad 23 will be described in detail below.

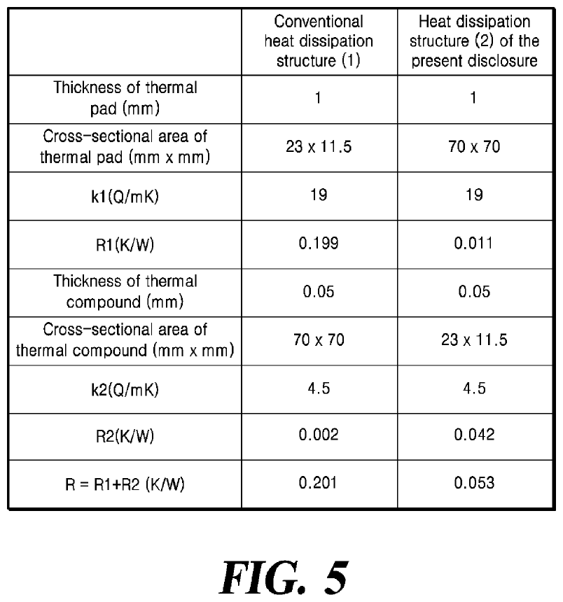

FIG. 5 is a table comparing thermal resistance between a conventional heat dissipation structure for a heating element and a heat dissipation structure for a heating element according to the present disclosure.

Thermal resistance refers to a property that hinders the transfer of heat of a material. The higher the thermal resistance, the smaller the heat flow through a material. That is, the smaller the thermal resistance of the heat dissipation structure 2 for a heating element, the greater the heat dissipation performance. The thermal resistance may be calculated using Equation 1.

$$R = L / ( k \times A ) \qquad ( 1 )$$

In Equation 1, “R” denotes a thermal resistance, “L” denotes a thickness of a heat-transferring material, “A” denotes a cross-sectional area of the heat-transferring material, and “k” denotes a thermal conductivity of the heat-transferring material.

Referring to FIG. 1 and FIG. 5, the vapor chamber 14 of the conventional heat dissipation structure 1 for a heating element and the vapor chamber 24 of the heat dissipation structure 2 for a heating element according to the present disclosure are the same, and thus, they are not taken into account when calculating thermal resistance.

Since the thermal pad 13 and the thermal compound 16 are connected in series, the thermal resistance of the conventional heat dissipation structure 1 for the heating element may be calculated as a sum of a thermal resistance R1 of the thermal pad 13 and a thermal resistance R2 of the thermal compound 16.

When the thickness, cross-sectional area, and thermal conductivity values of the thermal pad 13 are substituted into Equation 1, the thermal resistance R1 of the thermal pad 13 is 0.199 K/W. Likewise, when the thickness, cross-sectional area (referring to an area of application), and thermal conductivity values of the thermal compound 16 are substituted into Equation 1, the thermal resistance R2 of the thermal compound 16 is 0.002 K/W. That is, the thermal resistance R of the conventional heat dissipation structure 1 for the heating element is 0.201 K/W.

Since the thermal pad 23 and the thermal compound 26 are connected in series in the heat-dissipating structure 2 for the heating element according to the present disclosure, the thermal resistance R′ may be calculated as a sum of the respective thermal resistances.

When the thickness, cross-sectional area, and thermal conductivity of the thermal pad 23 are substituted into Equation 1, the thermal resistance R1′ of the thermal pad 23 is 0.011 K/W. Likewise, when the thickness, cross-sectional area (referring to an area of application), and thermal conductivity values of the thermal compound 26 are substituted into Equation 1, the thermal resistance R2′ of the thermal compound 26 is 0.042 K/W. That is, the thermal resistance R′ of the heat dissipation structure 2 for the heating element according to the present disclosure is 0.053 K/W.

The thermal resistance R′ of the heat dissipation structure 2 for the heating element according to the present disclosure is 26% of the thermal resistance R of the conventional heat dissipation structure 1 for the heating element. That is, the heat dissipation structure 2 for the heating element according to the present disclosure has an effect of improving heat dissipation performance, compared to the conventional heat dissipation structure 1 for the heating element. For example, when 30 W of heat is generated in the heating element, temperature of the conventional heat dissipation structure 1 for the heating element may increase by about 6 degrees due to the thermal resistance R (ΔT=Q×R, where ΔT indicates a temperature change and Q indicates a heat amount). On the other hand, in the heat dissipation structure 2 for the heating element according to the present disclosure, the temperature increases by about 1.6 degrees due to the thermal resistance R′. As a result, the temperature of the heat dissipation structure 2 for the heating element according to the present disclosure may be improved by about 4.5 degrees, compared to the conventional heat dissipation structure 1 for the heating element.

The above description is merely an example of the technical idea of the present embodiment, and various modifications and variations can be made by those skilled in the art without departing from the idea and scope of the present embodiment. Therefore, the present embodiments are not intended to limit the technical idea of the present embodiment, but to explain, and the scope of the technical idea of the present embodiment is not limited by these embodiments. The scope of protection of this embodiment should be construed according to the claims below, and all technical ideas within the scope equivalent thereto should be construed as being included in the scope of rights of this embodiment.

What is claimed is:

1. A heat dissipation structure for a heating element, wherein the heat dissipation structure uses a heat sink and comprises:
a plate;
the heating element comprising a housing configured to have one surface attached to the plate, and a heating unit positioned inside the housing and emitting heat;
a vapor chamber positioned in close contact with the heating element and configured to receive and diffuse the heat emitted from the heating element;
a thermal pad configured to transfer the heat received from the vapor chamber to the heat sink; and
the heat sink attached to the thermal pad and configured to emit the heat received from the thermal pad.

2. The heat dissipation structure of claim 1, further comprising:
a thermal compound applied between the heating element and the vapor chamber to transfer heat from the heating element to the vapor chamber.

3. The heat dissipation structure of claim 2, wherein the housing is configured so that an other surface of the housing, which is parallel to the one surface, is open.

4. The heat dissipation structure of claim 3, wherein the thermal compound is applied on an upper surface of the heating unit.

5. The heat dissipation structure of claim 3, wherein the vapor chamber comprises a protrusion unit of which at least a portion is to be inserted into the housing.

6. The heat dissipation structure of claim 1, wherein the thermal pad is configured to bond the vapor chamber and the heat sink.

7. The heat dissipation structure of claim 1, further comprising:
at least one connecting member configured to connect the vapor chamber and the plate.

8. The heat dissipation structure of claim 7, wherein the connecting member comprises:
a screw configured to pass through the vapor chamber; and
a spacer positioned between the vapor chamber and the plate and configured to be coupled to the screw.

9. The heat dissipation structure of claim 8, wherein the spacer is coupled to the plate by soldering.

10. The heat dissipation structure of claim 8, wherein the heat sink comprises a groove configured to accommodate at least a portion of the screw.
